(19) United States
(12) Patent Application Publication
(10) Pub. No.: US 2006/0223225 A1
(43) Pub. Date: Oct. 5, 2006

(54) Method, system, and apparatus for transfer of integrated circuit dies using an attractive force

(75) Inventors: Michael R. Arneson, Finksburg, MD (US); William R. Bandy, Gambrills, MD (US)

Correspondence Address: STERNE, KESSLER, GOLDSTEIN & FOX PLLC, 1100 NEW YORK AVENUE, N.W., WASHINGTON, DC, 20005, US

(73) Assignee: Symbol Technologies, Inc., Holtsville, NY (US)

(21) Appl. No.: 11/091,528

(22) Filed: Mar. 29, 2005

(51) Int. Cl. H01L 21/00

(52) U.S. Cl. 438/106

(57) ABSTRACT

A method, system, and apparatus for transferring integrated circuit dies is described. A die receptacle structure has a first surface. The first surface has a plurality of cells formed therein. Each cell is configured to contain an integrated circuit die. A bottom surface of each cell is configured to attract dies having a first material thereon. Example forces that can be used to attract dies into cells include a magnetic force, a chemical force, and an electrostatic force.

### BACKGROUND OF THE INVENTION

1. Field of the Invention

The present invention relates generally to the assembly of electronic devices. More particularly, the present invention relates to the transfer of integrated circuit (IC) dies to surfaces in high volumes.

2. Related Art

Pick and place techniques are often used to assemble electronic devices. Such techniques involve a manipulator, such as a robot arm, to remove integrated circuit (IC) chips or dies from a wafer and place them into a die carrier. The dies are subsequently mounted onto a substrate with other electronic components, such as antennas, capacitors, resistors, and inductors to form an electronic device.

Pick and place techniques involve complex robotic components and control systems that handle only one die at a time. This has a drawback of limiting throughput volume. Furthermore, pick and place techniques have limited placement accuracy, and have a minimum die size requirement.

One type of electronic device that may be assembled using pick and place techniques is an RFID “tag.” An RFID tag may be affixed to an item whose presence is to be detected and/or monitored. The presence of an RFID tag, and therefore the presence of the item to which the tag is affixed, may be checked and monitored by devices known as “readers.”

As market demand increases for products such as RFID tags, and as die sizes shrink, high assembly throughput rates and low production costs are crucial in creating commercially viable products. Accordingly, what is needed is a method and apparatus for high volume assembly of electronic devices, such as RFID tags, that overcomes these limitations.

### SUMMARY OF THE INVENTION

The present invention is directed to methods, systems, and apparatuses for producing one or more electronic devices, such as RFID tags, that each include a one or more dies. The dies each have one or more electrically conductive contact pads that provide for electrical connections to related electronics on a substrate.

According to the present invention, electronic devices are formed at much greater rates than conventionally possible. In one aspect, large quantities of dies can be transferred directly from a wafer to corresponding substrates of a web of substrates. In another aspect, large quantities of dies can be transferred from a support surface to corresponding substrates of a web of substrates. In another aspect, large quantities of dies can be transferred from a wafer or support surface to an intermediate surface, such as a die plate. The die plate may have cells formed in a surface thereof in which the dies reside. Otherwise, the dies can reside on a surface of the die plate. The dies of the die plate can then be transferred to corresponding substrates of a web of substrates.

Methods, systems, and apparatuses for transferring integrated circuit dies are described. In an aspect of the present invention, a die receptacle structure has a first surface. The first surface has a plurality of cells formed therein. Each cell is configured to contain an integrated circuit die. A bottom surface of each cell is configured to attract dies having a first material thereon. Dies are therefore attracted into the cells.

The die receptacle structure can be a web of electronic device substrates, such as RFID tag substrates, an intermediate die transfer surface, or other surface/structure.

Example forces that can be used to attract dies into cells include a magnetic force, a chemical force, and an electrostatic force.

These and other advantages and features will become readily apparent in view of the following detailed description of the invention. Note that the Summary and Abstract sections may set forth one or more, but not necessarily all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a block diagram of an exemplary RFID tag, according to an embodiment of the present invention.

FIGS. 2A and 2B show plan and side views of an exemplary die, respectively.

FIGS. 2C and 2D show portions of a substrate with a die attached thereto, according to example embodiments of the present invention.

FIG. 3 is a flowchart illustrating a device assembly process, according to embodiments of the present invention.

FIGS. 4A and 4B are plan and side views of a wafer having multiple dies affixed to a support surface, respectively.

FIG. 5 is a view of a wafer having separated dies affixed to a support surface.

FIG. 6 shows a system diagram illustrating example options for transfer of dies from wafers to substrates, according to embodiments of the present invention.

FIG. 7 shows example steps related to a flowchart for transferring dies into a receptacle structure, according to embodiments of the present invention.

FIG. 8 shows an example integrated circuit die or chip, according to an embodiment of the present invention.

FIGS. 9 and 10 show example die receptacle structures, according to embodiments of the present invention.

FIGS. 11-13 show example interaction between a die receptacle structure and dies, according to an example embodiment of the present invention.

FIG. 14 shows examples of dies having entered cells in an improperly oriented fashion.

FIG. 15 shows a system for attracting dies into cells of a die receptacle using electrostatic attraction.

FIG. 16 shows a surface having dies attached thereto, being positioned adjacent to a die receptacle structure, according to an example embodiment of the present invention.

FIG. 17 shows a system for transferring a plurality of dies in a gas or liquid medium to a die receptacle structure, according to an example embodiment of the present invention.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

1. Overview

The present invention provides improved processes and systems for assembling electronic devices, including RFID tags. The present invention provides improvements over previous processes. Conventional techniques include vision-based systems that pick and place dies one at a time onto substrates. The present invention can transfer multiple dies simultaneously. Vision-based pick and place systems are limited as far as the size of dies that may be handled, such as being limited to dies larger than 600 microns square. The present invention is applicable to dies 100 microns square and even smaller. Furthermore, yield is poor in conventional systems, where two or more dies may be accidentally picked up at a time, causing losses of additional dies. The present invention allows for improved yield values.

The present invention provides an advantage of simplicity. Conventional die transfer tape mechanisms may be used by the present invention. Furthermore, much higher fabrication rates are possible. Previous techniques processed 5-8 thousand units per hour. The present invention provides improvements in these rates by a factor of N. For example, embodiments of the present invention can process dies 5 times as fast as conventional techniques, at 100 times as fast as conventional techniques, and at even faster rates. Furthermore, because the present invention allows for flip-chip die attachment techniques, wire bonds are not necessary. However, in embodiments, the present invention is also applicable to wire bonded die embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Elements of the embodiments described herein may be combined in any manner. Example RFID tags are described in section 1.1. Assembly embodiments for devices are described in section 1.2. More detailed assembly embodiments for devices are described in section 2.

1.1 Exemplary Electronic Device

The present invention is directed to techniques for producing electronic devices, such as RFID tags. For illustrative purposes, the description herein primarily relates to the production of RFID tags. However, the invention is also adaptable to the production of further electronic device types (e.g., electronic devices including one or more IC dies or other electrical components mounted thereto), as would be understood by persons skilled in the relevant art(s) from the teachings herein. Furthermore, for purposes of illustration, the description herein primarily describes attachment of dies to substrates. However, embodiments of the present invention are also applicable to the attachment of other types of electrical components to substrates, including any type of surface mount component (e.g., surface mount resistors, capacitors, inductors, diodes, etc.), as would be understood by persons skilled in the relevant art(s).

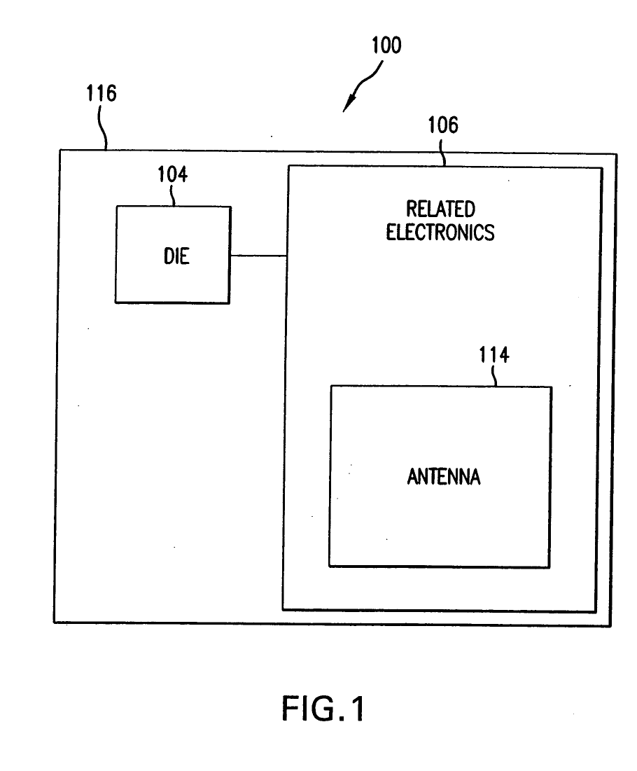

FIG. 1 shows a block diagram of an exemplary RFID tag 100, according to an embodiment of the present invention. As shown in FIG. 1, RFID tag 100 includes a die 104 and related electronics 106 located on a tag substrate 116. Related electronics 106 includes an antenna 114 in the present example. Die 104 can be mounted onto antenna 114 of related electronics 106, or on other locations of substrate 116. As is further described elsewhere herein, die 104 may be mounted in either a pads up or pads down orientation.

RFID tag 100 may be located in an area having a large number, population, or pool of RFID tags present. Tag 100 receives interrogation signals transmitted by one or more tag readers. According to interrogation protocols, tag 100 responds to these signals. The response(s) of tag 100 includes information that the reader can use to identify the corresponding tag 100. Once the tag 100 is identified, the existence of tag 100 within a coverage area defined by the tag reader is ascertained.

RFID tag 100 may be used in various applications, such as inventory control, airport baggage monitoring, as well as security and surveillance applications. Thus, tag 100 can be affixed to items such as airline baggage, retail inventory, warehouse inventory, automobiles, compact discs (CDs), digital video discs (DVDs), video tapes, and other objects. Tag 100 enables location monitoring and real time tracking of such items.

In the present embodiment, die 104 is an integrated circuit that performs RFID operations, such as communicating with one or more tag readers (not shown) according to various interrogation protocols. Exemplary interrogation protocols are described in U.S. Pat. No. 6,002,344 issued Dec. 14, 1999 to Bandy et al. entitled System and Method for Electronic Inventory, and U.S. patent application Ser. No. 10/072,885, filed on Feb. 12, 2002, both of which are incorporated by reference herein in their entirety. Die 104 includes a plurality of contact pads that each provide an electrical connection with related electronics 106.

Related electronics 106 are connected to die 104 through a plurality of contact pads of IC die 104. In embodiments, related electronics 106 provide one or more capabilities, including RF reception and transmission capabilities, impedance matching, sensor functionality, power reception and storage functionality, as well as additional capabilities. The components of related electronics 106 can be printed onto a tag substrate 116 with materials, such as conductive inks. Examples of conductive inks include silver conductors 5000, 5021, and 5025, produced by DuPont Electronic Materials of Research Triangle Park, N.C. Other example materials or means suitable for printing related electronics 106 onto tag substrate 116 include polymeric dielectric composition 5018 and carbon-based PTC resistor paste 7282, which are also produced by DuPont Electronic Materials of Research Triangle Park, N.C. Other materials or means that may be used to deposit the component material onto the substrate would be apparent to persons skilled in the relevant art(s) from the teachings herein. In addition to these materials, portions of related electronics 106, such as antenna 114, can be made from aluminum, copper, or any other suitable material.

As shown in FIG. 1, tag substrate 116 has a first surface that accommodates die 104, related electronics 106, as well as further components of tag 100. Tag substrate 116 also has a second surface that is opposite the first surface. An adhesive material and/or backing can be included on the second surface. When present, an adhesive backing enables tag 100 to be attached to objects, such as books, containers, and consumer products. Tag substrate 116 is made from a material, such as polyester, paper, plastic, fabrics such as cloth, and/or other materials such as commercially available Tyvec®.

In some implementations of tags 100, tag substrate 116 can include an indentation, “cavity,” or “cell” (not shown in FIG. 1) that accommodates die 104. An example of such an implementation is included in a “pads up” orientation of die 104.

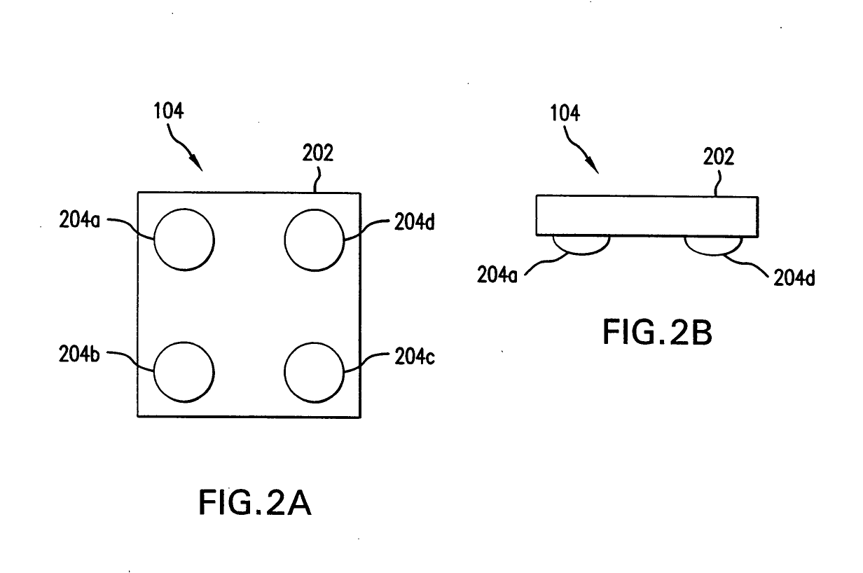

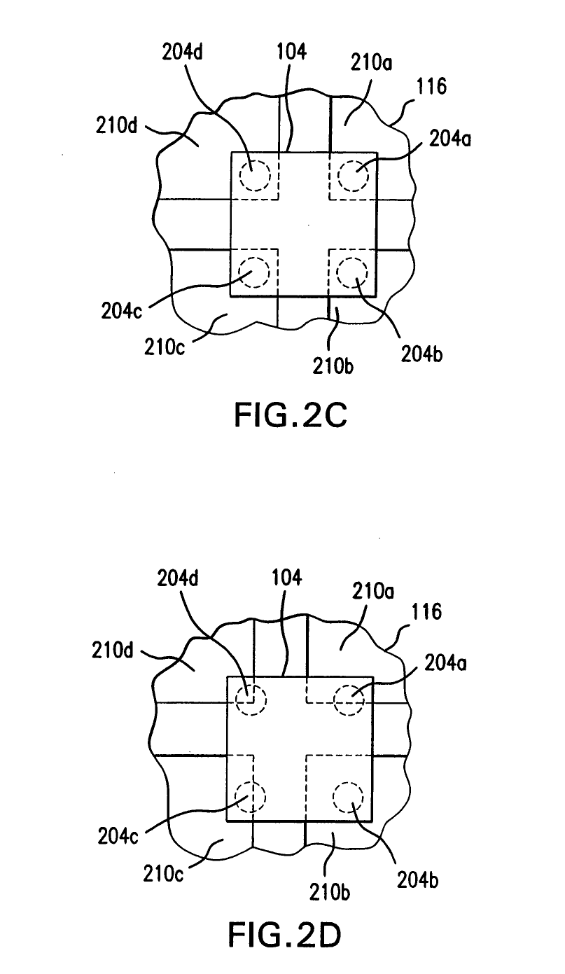

FIGS. 2A and 2B show plan and side views of an example die 104. Die 104 includes four contact pads 204a-d that provide electrical connections between related electronics 106 (not shown) and internal circuitry of die 104. Note that although four contact pads 204a-d are shown, any number of contact pads may be used, depending on a particular application. Contact pads 204 are typically made of an electrically conductive material during fabrication of the die. Contact pads 204 can be further built up if required by the assembly process, by the deposition of additional and/or other materials, such as gold and solder flux. Such post processing, or “bumping,” will be known to persons skilled in the relevant art(s).

FIG. 2C shows a portion of a substrate 116 with die 104 attached thereto, according to an example embodiment of the present invention. As shown in FIG. 2C, contact pads 204a-d of die 104 are coupled to respective contact areas 210a-d of substrate 116. Contact areas 210a-d provide electrical connections to related electronics 106. The arrangement of contact pads 204a-d in a rectangular (e.g., square) shape allows for flexibility in attachment of die 104 to substrate 116, and good mechanical adherement. This arrangement allows for a range of tolerance for imperfect placement of IC die 104 on substrate 116, while still achieving acceptable electrical coupling between contact pads 204a-d and contact areas 210a-d. For example, FIG. 2D shows an imperfect placement of IC die 104 on substrate 116. However, even though IC die 104 has been improperly placed, acceptable electrical coupling is achieved between contact pads 204a-d and contact areas 210a-d.

Contact pads 204 can be attached to contact areas 210 of substrate 116 using any suitable conventional or other attachment mechanism, including solder, an adhesive material (including isotropic and anisotropic adhesives), mechanical pressure (e.g., being held in place by an encapsulating material), etc.

For example, in some embodiments, an oxide layer, such as an aluminum oxide layer may form or be present on antenna contact areas, such as aluminum contact areas. Thus, certain adhesive materials may be beneficial to attach contact pads 204 to contact areas 210 through the oxide layer. For example, some adhesive materials, such as an anisotropic adhesive, can include solvents that penetrate the oxide barrier.

In example embodiments, an anisotropic adhesive tape or a pre-cured anisotropic “glue” can be applied to the active surface of dies on a wafer. When the wafer is singulated (as described above), the adhesive material is also singulated, and thus in this fashion, each die may be coated with the adhesive material prior to attachment to a substrate or other surface. A pre-cured anisotropic adhesive material can be reflowed, such as by re-heating, to prepare it for attachment.

In another example embodiment for making contact through an oxide layer, metal bumps can be formed on contact pads 204. For example, the metal used could be a soft nobel metal, such as palladium. The die could be pushed against the contact areas, causing the metal bumped pads of the die to penetrate the oxide layer, to make contact with the contact areas of the substrate.

In another example embodiment, die contact pads may be attached to substrate contact areas without an adhesive, to form a non-adhesive bond. For example, focused ultrasound (such as created by a transducer) may be used to “scrub” through the oxide layer. Then, for example, a nickel-based contact pad material, such as gold-nickel die bond pads, can make contact with aluminum contact areas of an aluminum substrate.

For further example embodiments for adhesive materials and processes for bonding die contact pads to contact areas of a substrate, please refer to U.S. Ser. No. 10/429,803, titled “Method and System for Forming a Die Frame and for Transferring Dies Therewith,” filed May 6, 2003 (Attorney Docket No. 1689.0110005), which is incorporated herein by reference in its entirety.

Note that although FIGS. 2A-2D show the layout of four contact pads 204a-d collectively forming a rectangular shape, greater or lesser numbers of contact pads 204 may be used. Furthermore, contact pads 204a-d may be laid out in other shapes in other embodiments.

1.2 Device Assembly

The present invention is directed to continuous-roll assembly techniques and other techniques for assembling electronic devices, such as RFID tag 100. Such techniques involve a continuous web (or roll) of the material of the substrate 116 that is capable of being separated into a plurality of devices. Alternatively, separate sheets of the material can be used as discrete substrate webs that can be separated into a plurality of devices. As described herein, the manufactured one or more devices can then be post processed for individual use. For illustrative purposes, the techniques described herein are made with reference to assembly of tags, such as RFID tag 100. However, these techniques can be applied to other tag implementations and other suitable devices, as would be apparent to persons skilled in the relevant art(s) from the teachings herein.

The present invention advantageously eliminates the restriction of assembling electronic devices, such as RFID tags, one at a time, allowing multiple electronic devices to be assembled in parallel. The present invention provides a continuous-roll technique that is scalable and provides much higher throughput assembly rates than conventional pick and place techniques.

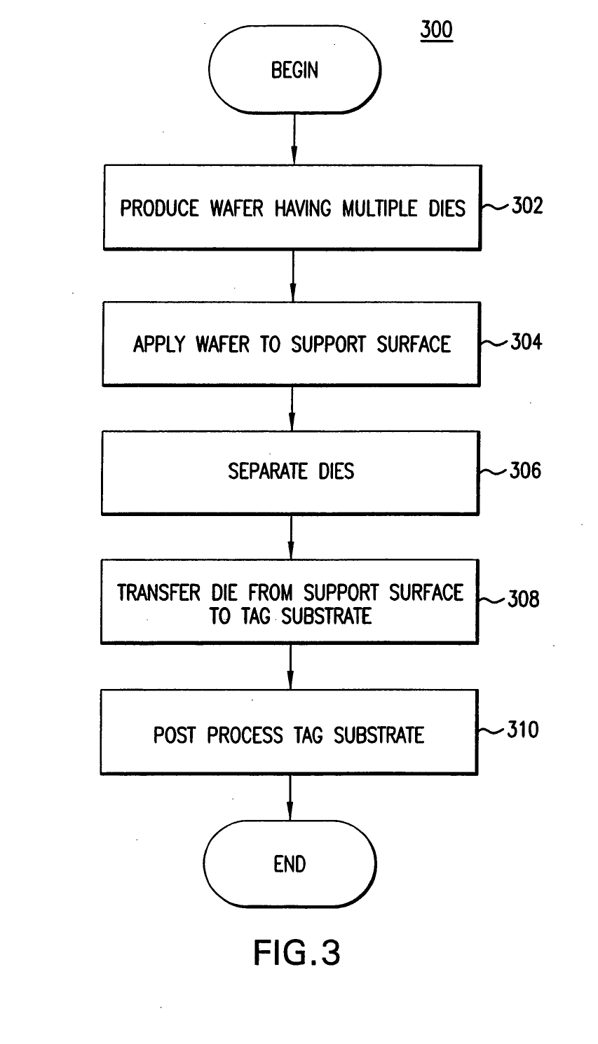

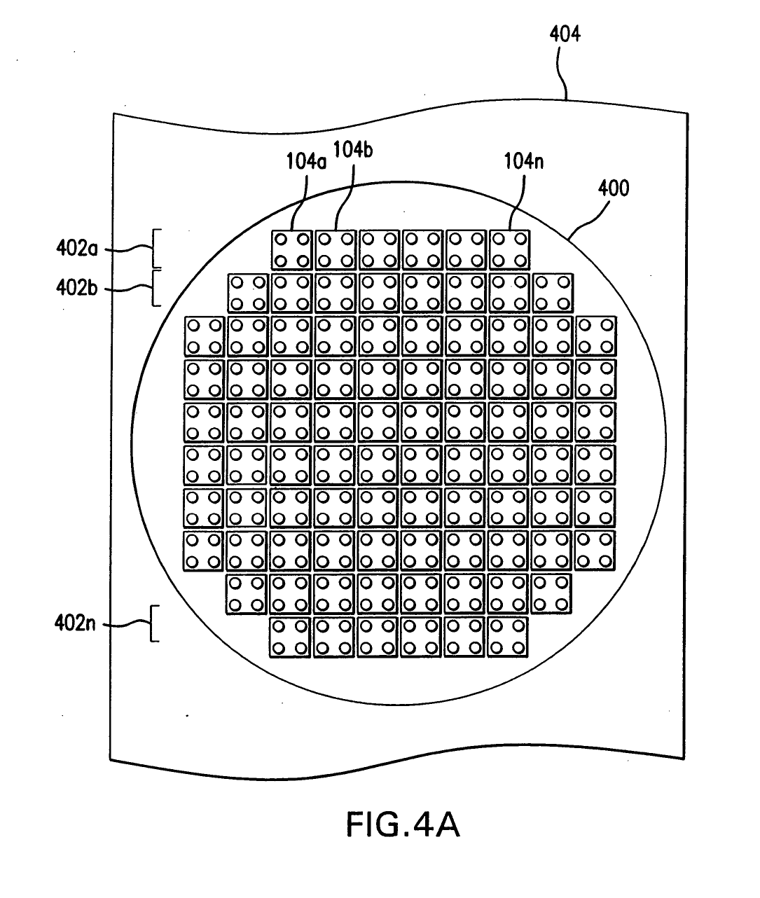

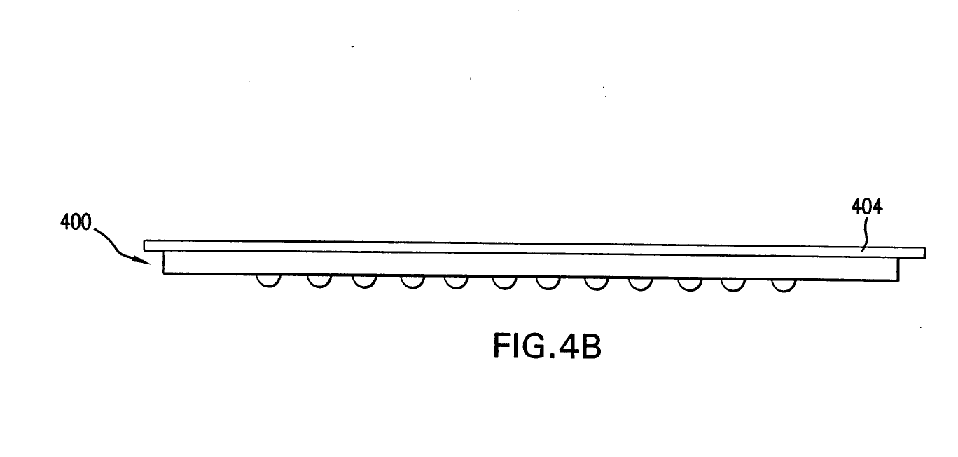

FIG. 3 shows a flowchart 300 with example steps relating to continuous-roll production of RFID tags 100, according to example embodiments of the present invention. FIG. 3 shows a flowchart illustrating a process 300 for assembling tags 100. The process 300 depicted in FIG. 3 is described with continued reference to FIGS. 4A and 4B. However, process 300 is not limited to these embodiments.

Process 300 begins with a step 302. In step 302, a wafer 400 (shown in FIG. 4A) having a plurality of dies 104 is produced. FIG. 4A illustrates a plan view of an exemplary wafer 400. As illustrated in FIG. 4A, a plurality of dies 104a-n are arranged in a plurality of rows 402a-n.

In a step 304, wafer 400 is optionally applied to a support structure or surface 404. Support surface 404 includes an adhesive material to provide adhesiveness. For example, support surface 404 may be an adhesive tape that holds wafer 400 in place for subsequent processing. For instance, in example embodiments, support surface 404 can be a “green tape” or “blue tape,” as would be understood by persons skilled in the relevant art(s). FIG. 4B shows an example view of wafer 400 in contact with an example support surface 404. In some embodiments, wafer 400 is not attached to a support surface, and can be operated on directly.

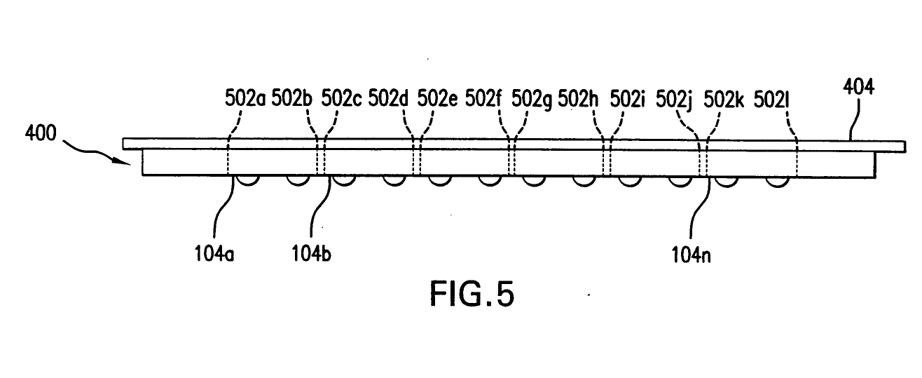

In a step 306, the plurality of dies 104 on wafer 400 are separated or “singulated”. For example, step 306 may include scribing wafer 400 using a wafer saw, laser etching, or other singulation mechanism or process. FIG. 5 shows a view of wafer 400 having example separated dies 104 that are in contact with support surface 404. FIG. 5 shows a plurality of scribe lines 502a-l that indicate locations where dies 104 are separated.

In a step 308, the plurality of dies 104 is transferred to a substrate. For example, dies 104 can be transferred from support surface 404 to tag substrates 116. Alternatively, dies 104 can be directly transferred from wafer 400 to substrates 116. In an embodiment, step 308 may allow for “pads down” transfer. Alternatively, step 308 may allow for “pads up” transfer. As used herein the terms “pads up” and “pads down” denote alternative implementations of tags 100. In particular, these terms designate the orientation of connection pads 204 in relation to tag substrate 116. In a “pads up” orientation for tag 100, die 104 is transferred to tag substrate 116 with pads 204a-204d facing away from tag substrate 116. In a “pads down” orientation for tag 100, die 104 is transferred to tag substrate 116 with pads 204a-204d facing towards, and in contact with tag substrate 116.

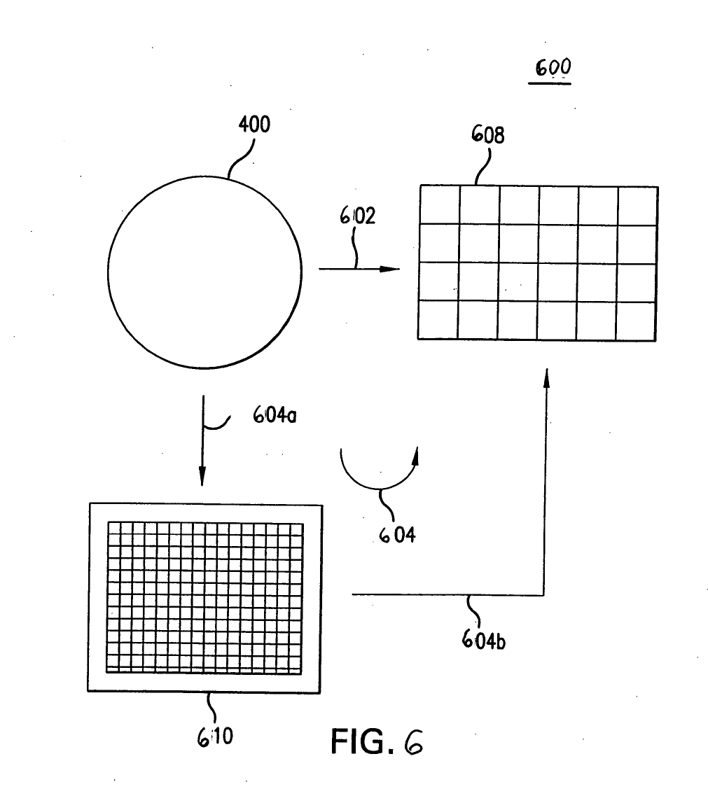

Note that step 308 may include multiple die transfer iterations. For example, in step 308, dies 104 may be directly transferred from a wafer 400 to substrates 116. Alternatively, dies 104 may be transferred to an intermediate structure, and subsequently transferred to substrates 116. Example embodiments of such die transfer options are described below in reference to FIG. 6.

Note that steps 306 and 308 can be performed simultaneously in some embodiments. This is indicated in FIG. 3 by step 320, which includes both of steps 306 and 308.

Example embodiments of the steps of flowchart 300, are described in co-pending applications, U.S. Ser. No. 10/866,148, titled “Method and Apparatus for Expanding a Semiconductor Wafer”; U.S. Ser. No. 10/866,150, “Method, System, and Apparatus for Transfer of Dies Using a Die Plate Having Die Cavities”; U.S. Ser. No. 10/866,253, titled “Method, System, and Apparatus for Transfer of Dies Using a Die Plate”; U.S. Ser. No. 10/866,159, titled “Method, System, and Apparatus for Transfer of Dies Using a Pin Plate”; and U.S. Ser. No. 10/866,149, titled “Method, System, and Apparatus for High Volume Transfer of Dies,” each of which is herein incorporated by reference in its entirety.

In a step 310, post processing is performed. For example, during step 310, assembly of RFID tag(s) 100 is completed. Example post processing of tags that can occur during step 310 are provided as follows:

(a) Separating or singulating tag substrates 116 from the web or sheet of substrates into individual tags or “tag inlays.” A “tag inlay” or “inlay” is used generally to refer to an assembled RFID device that generally includes a integrated circuit chip and antenna formed on a substrate.

(b) Forming tag “labels.” A “label” is used generally to refer to an inlay that has been attached to a pressure sensitive adhesive (PSA) construction, or laminated and then cut and stacked for application through in-mould, wet glue or heat seal application processes, for example. A variety of label types are contemplated by the present invention. In an embodiment, a label includes an inlay attached to a release liner by pressure sensitive adhesive. The release liner may be coated with a low-to-non-stick material, such as silicone, so that it adheres to the pressure sensitive adhesive, but may be easily removed (e.g., by peeling away). After removing the release liner, the label may be attached to a surface of an object, or placed in the object, adhering to the object by the pressure sensitive adhesive. In an embodiment, a label may include a “face sheet”, which is a layer of paper, a lamination, and/or other material, attached to a surface of the inlay opposite the surface to which the pressure sensitive material attaches. The face sheet may have variable information printed thereon, including product identification regarding the object to which the label is attached, etc.

(c) Testing of the features and/or functionality of the tags.

FIG. 6 further describes example flows for step 308 of FIG. 3. FIG. 6 shows a high-level system diagram 600 that provides a representation of the different modes or paths of transfer of dies from wafers to substrates. FIG. 6 shows a wafer 400, a substrate web 608, and a transfer surface 610. Two paths are shown in FIG. 6 for transferring dies, a first path 602, which is a direct path, and a second path 604, which is a path having intermediate steps.

For example, as shown in FIG. 6, first path 602 leads directly from wafer 400 to substrate web 608. In other words, dies can be transferred from wafer 400 to substrates of substrate web 608 directly, without the dies having first to be transferred from wafer 400 to another surface or storage structure. However, as shown in path 604, at least two steps are required, path 604A and path 604B. For path 604A, dies are first transferred from wafer 400 to an intermediate transfer surface 610. The dies then are transferred from transfer surface 610 via path 604B to the substrates of web 608. Paths 602 and 604 each have their advantages. For example, path 602 can have fewer steps than path 604, but can have issues of die registration, and other difficulties. Path 604 typically has a larger number of steps than path 602, but transfer of dies from wafer 400 to a transfer surface 610 can make die transfer to the substrates of web 608 easier, as die registration may be easier.

Any of the intermediate/transfer surfaces and final substrate surfaces may or may not have cells formed therein for dies to reside therein. Various processes described below may be used to transfer multiple dies simultaneously between first and second surfaces, according to embodiments of the present invention. In any of the processes described herein, dies may be transferred in either pads-up or pads-down orientations from one surface to another.

Elements of the die transfer processes described herein may be combined in any way, as would be understood by persons skilled in the relevant art(s). Example die transfer processes, and related example structures for performing these processes, are further described in the following subsections.

2. Die Transfer Embodiments

Embodiments for transferring dies to a receptacle structure having cells or cavities formed therein are described in this section. For example, these embodiments can be used to perform step 308 of FIG. 3, which is further described above. These embodiments are described for illustrative purposes, and are not limiting. Further embodiments will be apparent to persons skilled in the relevant art(s) from the teachings herein. These further embodiments are within the scope and spirit of the present invention.

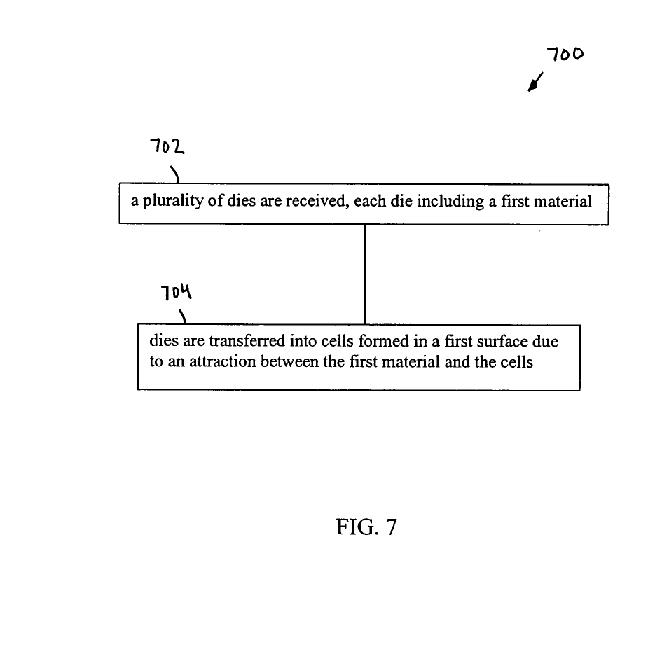

FIG. 7 shows example steps related to a flowchart 700 for transferring dies into a receptacle structure, according to embodiments of the present invention. The steps shown in FIG. 7 are described in detail below. Further operational and structural embodiments of the present invention will be apparent to persons skilled in the relevant art(s) based on the following discussion.

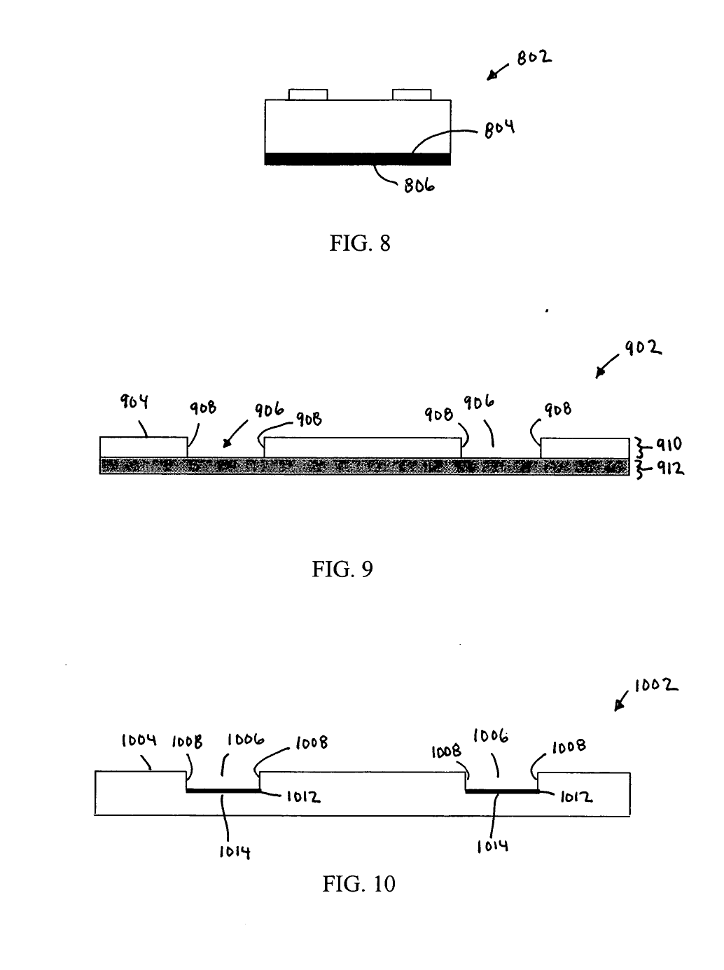

Flowchart 700 begins with step 702. In step 702, a plurality of dies are received, each die having a surface at least partially covered with a first material. For example, FIG. 8 shows a die 802, according to an embodiment of the present invention. As shown in FIG. 8, die 802 has a surface 804 covered with a first material 806. In embodiments, any portion of any surface of die 802 may be covered with first material 806, depending on the particular application.

In step 704, the dies are transferred into cells formed in a first surface due to an attraction between the first material and the cells. In embodiments, the first surface is a surface of a die receptacle structure. In example embodiments, the die receptacle structure is a substrate, a web of substrates, or is die holder (e.g., an intermediate die transfer surface). The die receptacle structure has cells/cavities formed in a surface. There can be any number of cells, and the cells can be as densely packed or spread out in the surface as required by the particular application.

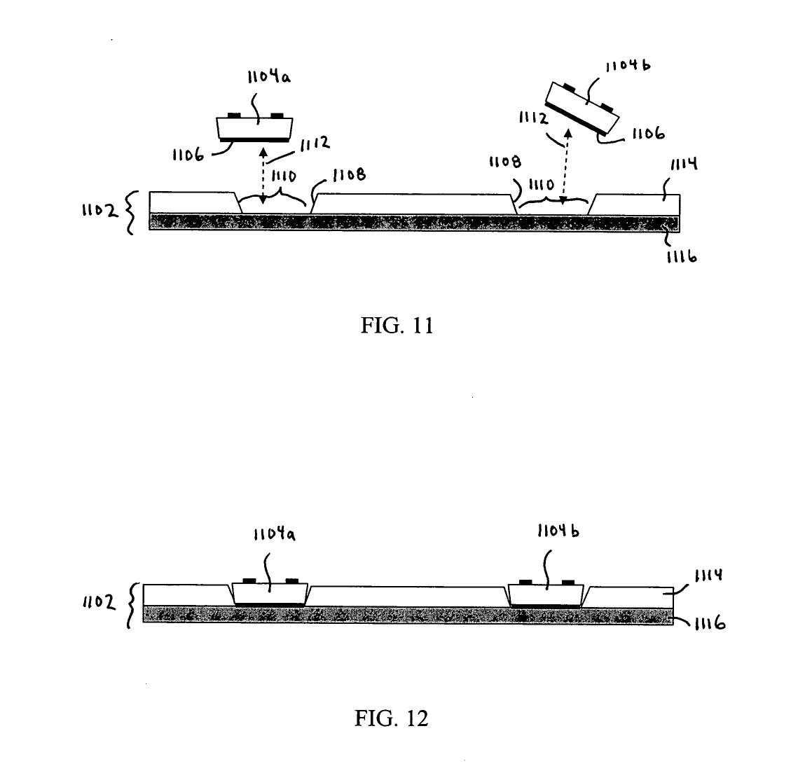

For example, FIGS. 9 and 10 show example die receptacle structures 902 and 1002, according to embodiments of the present invention. Die receptacle structure 902 of FIG. 9 has a first surface 904, having a plurality of cells 906 formed therein. Die receptacle structure 1002 of FIG. 10 has a first surface 1004, having a plurality of cells 1006 formed therein. Cells 906 and 1006 are configured such that an IC die can reside therein. Any number of cells can be formed in a die receptacle structure, including 10s, 100s, 1000s, and greater numbers of cells. Cells 906 and 1006 can be shaped to conform to any size and shape IC die. For example, cells 906 and 1006 can have sides 908 and 1008, respectively, that are perpendicular to first surface 904 and first surface 1004, respectively, or that are angled with respect to first surface 904 and first surface 1004 (e.g., such as shown in FIG. 11, further described below).

As described above with respect to step 704, dies are transferred into cells due to an attraction between the first material and the cells. In example embodiments, first material 806 may exert an attractive force on a material of the cells, a material of the cells may exert an attractive force on first material 806, or first material 806 and a material of the cells may each exert an attraction on the other.

For example, die receptacle structure 902 includes a first layer 910 having cells 906 formed therethrough. First layer 910 is attached to a second layer 912 that forms the bottom surface 914 of each cell 906. First layer 910 can be formed of any suitable material, including glass, plastic, a polymer, etc. Second layer 912 is substantially entirely formed of a material that exerts an attractive force on first material 806 and/or is attracted by first material 806.

In the alternative embodiment of FIG. 10, bottom surface 1014 of each cell 1006 includes a material 1012 thereon that exerts an attractive force on first material 806 and/or is attracted by first material 806 (rather than having an entire layer of attractive material as in FIG. 9).

Example materials for first material 806, first layer 910, and material 1012 are described below.

FIGS. 11-13 show example interaction between a die receptacle structure 1102 and dies 1104, according to an example embodiment of the present invention. As shown in FIG. 11, die receptacle structure 1102 includes a first layer 1114 and a second layer 1116. Dies 1104a and 1104b have angled sides to have an overall trapezoidal shaped cross-section. A surface of dies 1104a and 1104b is covered with a first material 1106. Cells 1110 in first layer 1114 have angled sides 1108 (e.g., at an angle other than 90 degrees with respect to the bottom surface of cells 1110) configured to conform to the trapezoidal shape of dies 1104a and 1104b. As further described below, due to their trapezoidal shape, dies 1104a and 1104b cannot reside completely in cells 1110 unless the side of a die 1104 having first material 1106 thereon entirely enters cells 1102, such as shown in FIG. 12.

Dies 1104a and 1104b are attracted into cells 1110 by attractive force 1112 shown in FIG. 11. In other words, after a die 1104 comes close enough to a cell 1110 to be sufficiently attracted by attractive force 1112 (depending on a strength and effective range of attractive force 1112), the die 1104 will enter and reside in the respective cell 1110. Attractive force 1112 acts between first material 1106 of dies 1104a-b and second layer 1116 of die receptacle structure 1102 to attract and hold dies 1104a-b in cells 1110.

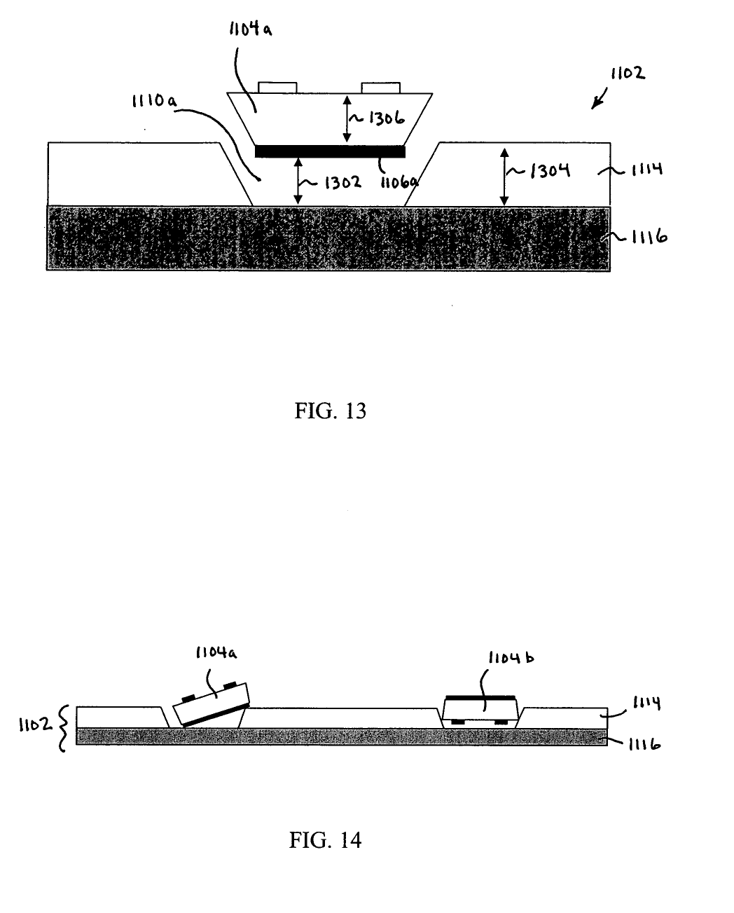

FIG. 13 shows a view of a cell 1110a in die receptacle structure 1102. Second layer 1116 at the bottom of cell 1110a and first material layer 1106a of die 1104a are attracted to each other. In an embodiment, first material layer 1106a must come within a distance 1302 to layer 1116 in order to be sufficiently attracted into cell 1110a. Distance 1302 depends on a strength and effective range of attractive force 1112, which may be adjusted according to the particular application. Thus, in an embodiment, first layer 1114 of die receptacle structure 1102 is formed to a thickness 1304 that is greater than distance 1302 so that dies 1104 do not become attached to first layer 1114 outside of cells 1110. Furthermore, dies 1104 are configured to have a thickness 1306 such that dies 1104 cannot get close enough to second layer 1116 when they are upside down to be sufficiently attracted to second layer 1116.

FIG. 12 shows properly oriented dies 1104a and 1104b residing in cells 1110, having been attracted into cells 1110 due to attractive force 1112. FIG. 14 shows dies 1104a and 1104b having entered cells 1110 in an improperly oriented fashion. Because of their orientation, a strength of attractive force 1112 on dies 1104a and 1104b is weaker in FIG. 14 relative to the strength of attractive force 1112 on dies 1104a and 1104b in FIG. 12. This is because in FIG. 12, the entirety of first material 1106 of dies 1104a and 1104b is able to come into direct, close contact with second layer 1116. Relative to FIG. 12, in FIG. 14, first material 1106 of die 1104a is less close to (i.e., partially in contact with) second layer 1116, and first material 1106 of die 1104b is even less close to (i.e., not at all in contact with) second layer 1116.

As further described below, in an embodiment, improperly oriented dies and improperly attached dies can be shaken or blown loose through various means, if needed. Furthermore, in an embodiment, first material 1106 can be positioned on the bottom surface of dies 1104, in a central region away from the edges of the bottom surface of dies 1104, to decrease a likelihood that dies 1104 will attach to cells 1110 in the fashion that die 1104a is shown in FIG. 14.

In embodiments, systems can be configured in a variety of ways to attract dies into cells. For example, first material 1106 and second layer 1116 may be configured to be attracted by various forces, including magnetic, electrostatic, chemical, and/or other forces.

For example, in an embodiment, a magnetic force can be used to attract dies 1104 into cells 1110. Referring to FIG. 11 for illustrative purposes, first material 1106 can be a magnetic material having a magnetic attraction with second layer 1116, which may include a magnetic material or may be a metal. Alternatively, first material 1106 can be a metal that is attracted to a magnetic material of second layer 1116. First material 1106 and/or second layer 1116 can include any suitable magnetic material, including magnetic nanoparticles such as a nanoferrite magnetic material. Alternatively, when first material 1106 or second layer 1116 include a metallic material, any suitable metal can be used, including a ferrite material.

In another embodiment, a chemical bonding force can be used to attract dies 1104 into cells 1110. For example, first material 1106 can be a material chemically attracted to a material of layer 1116. Any suitable chemical material or combination of chemical material(s) can be used. For example, first material 1106 and second layer 1116 can be configured to be attracted by Van der Wahls forces (which can also be viewed as an electrostatic-type force). Alternatively, for example, nano-particles, proteins, or pheromones can be used to create an attraction.

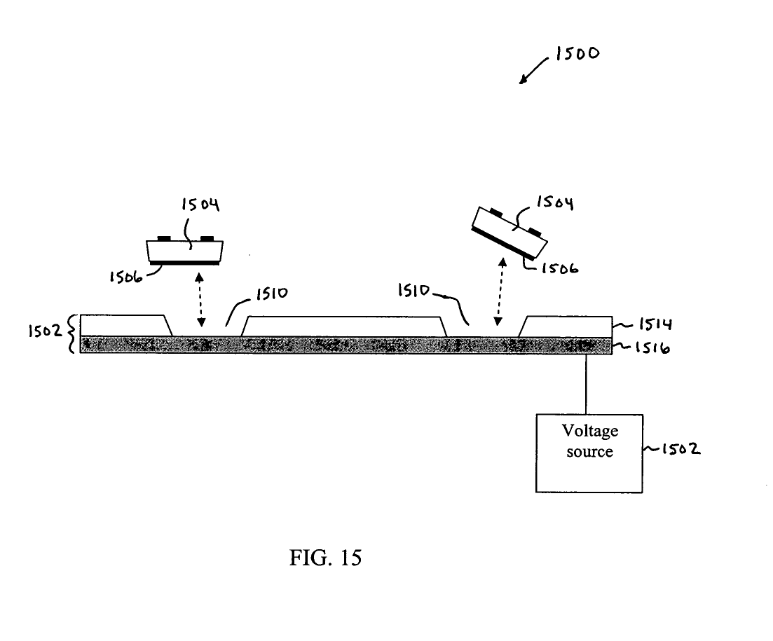

In another example embodiment, an electrostatic attraction can be used to attract dies into cells. For example, FIG. 15 shows a system 1500 for attracting dies 1504 into cells 1510 of a die receptacle 1502 using electrostatic attraction. As shown in FIG. 15, a voltage source 1502 is coupled to second layer 1516 to apply a bias to second layer 1516. Second layer 1516, which may be metal, for example, is charged by voltage source 1502. Charged second layer 1516 attracts first material 1506 of dies 1504, to transfer dies 1504 into cells 1510.

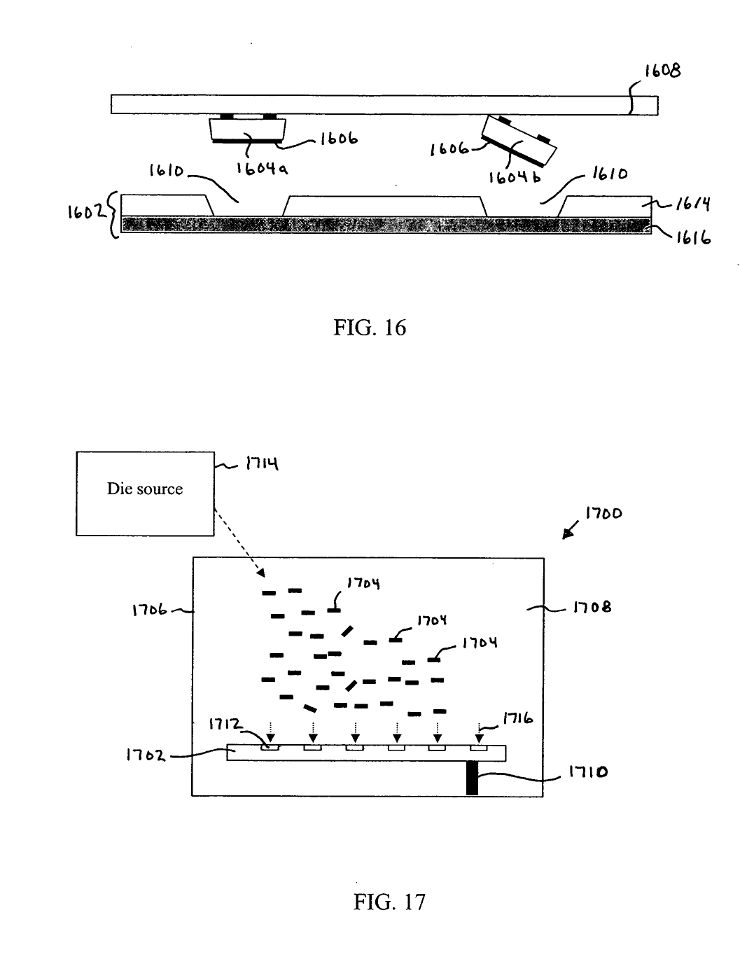

In embodiments, dies may be transferred to a die receptacle structure through a gas, vacuum, or liquid medium. Furthermore, the dies may be freely circulating when brought near the die receptacle structure, or may be attached to a supply surface when brought near the die receptacle structure. When attached to a supply surface, the attractive force may be used to partially or completely detach dies from the supply surface. For example, FIG. 16 shows a surface 1608 having dies 1604 attached thereto, being positioned adjacent to a die receptacle structure 1602. In example embodiments, surface 1608 can be a surface of a body such as a die plate, wafer plate, an adhesive tape (e.g., blue tape, green tape), or other surface. As shown in FIG. 16, die 1604a is fully attached to surface 1608, while die 1604b is partially detached to surface 1608 (i.e., hanging). An attractive force between first material 1606 of dies 1604a-b and second layer 1616 may be configured to aid in detaching fully-attached die 1604a from surface 1608, and/or to detach partially-attached die 1604b from surface 1608. Surface 1608 can be moved closer to or farther away from die receptacle surface 1602 as needed (e.g., depending upon the strength and/or range of the attractive force, etc.).

FIG. 17 shows a system 1700 for transferring a plurality of dies 1704 in a gas or liquid medium to a die receptacle structure 1702, according to an example embodiment of the present invention. System 1700 includes a die receptacle structure 1702, a container 1706, a gas or liquid 1708, a mount 1710, and a die source 1714.

In the following description of FIG. 17, container 1706 holds a liquid 1708. However, alternatively, as mentioned above, container 1706 may hold a gas. Loose dies 1704 are deposited into container 1706 from a die source 1714. Die receptacle structure 1702 is supported by mount 1710. Attractive force 1716 attracts dies 1704 through liquid 1708 into cells 1712 of die receptacle structure 1702. Mount 1710 may optionally be used to move and/or vibrate die receptacle structure 1702 to circulate dies 1704, to enable dies 1704 to work their way into cells 1712, and/or to shake loose dies 1704 that are attached to areas of die receptacle structure 1702 outside of cells 1712.

Additionally or alternatively, a liquid source may be used to circulate dies 1704 for a similar effect to vibrating die receptacle structure 1702. In a gas medium embodiment, a gas source (not shown) may be used to “blow” on dies 1704 to circulate them for a similar effect.

In an electrostatic attraction embodiment, mount 1710 may provide an electrical connection for a bias voltage to be coupled to die receptacle structure 1702.

Note that in embodiments, die receptacle structures, such as die receptacle structure 1702, can be used in flowchart 300, such as in step 308, as an intermediate step in transferring dies to from a support surface to a substrate. For example, a plurality of dies 104 can be transferred from support surface 404 to die receptacle structure 1702, according to the example embodiments described herein. The dies 104 can be subsequently transferred from die receptacle structure 1702 to electronic device substrates, such as RFID tags. Alternatively, in an embodiment, die receptacle structure 1702 is a sheet/roll of electronic device substrates, and thus, die receptacle structure 1702 can be a final target surface for the dies 104. Thus, in embodiments, die receptacle structures can be substrate web 608 and/or transfer surface 610, shown in FIG. 6.

3.0 Conclusion

While various embodiments of the present invention have been described above, it should be understood that they have been presented by way of example, and not limitation. It will be apparent to persons skilled in the relevant arts that various changes in form and detail can be made therein without departing from the spirit and scope of the invention. Thus the present invention should not be limited by any of the above-described exemplary embodiments, but should be defined only in accordance with the following claims and their equivalents.

What is claimed is:

1. A method for transferring a plurality of integrated circuit dies, comprising:
(a) receiving a plurality of dies, wherein each die of the plurality of dies has a surface at least partially covered with a first material; and
(b) transferring dies of the plurality of dies into cells formed in a first surface, wherein the dies are transferred into the cells due to an attraction between the first material and the cells.

2. The method of claim 1, wherein step (a) comprises:
receiving a second surface having the plurality of dies thereon; and
releasing the plurality of dies from the second surface.

3. The method of claim 1, wherein the first surface is located in a liquid, wherein step (a) comprises:
depositing the plurality of dies into the liquid.

4. The method of claim 1, wherein step (b) comprises:
using a magnetic force to attract dies of the plurality of dies into the cells.

5. The method of claim 4, wherein the first material is magnetic, wherein said using step comprises:
using a magnetic material of the cells to attract the magnetic first material, thereby attracting dies of the plurality of dies into the cells.

6. The method of claim 4, wherein the first material is a metal, wherein said using step comprises:
using a magnetic material of the cells to attract the metal, thereby attracting dies of the plurality of dies into the cells.

7. The method of claim 3, wherein the first material is magnetic, wherein said using step comprises:
allowing the magnetic first material to be attracted to a metal material of the cells, thereby attracting dies of the plurality of dies into the cells.

8. The method of claim 1, wherein step (b) comprises:
using a chemical attraction to attract dies of the plurality of dies into the cells.

9. The method of claim 8, wherein said using step comprises:
applying a second material to an inner surface of the cells, wherein the first material and second material are chemically attracted.

10. The method of claim 1, wherein step (b) comprises:
using an electrostatic attraction to attract dies of the plurality of dies into the cells.

11. The method of claim 10, wherein step (b) comprises: applying a bias voltage to the first surface to induce the electrostatic attraction.

12. A system for transferring a plurality of integrated circuit dies, comprising:
a die receptacle structure having a first surface, wherein the first surface has a plurality of cells formed therein, each cell configured to contain an integrated circuit die;
wherein a bottom surface of each cell is configured to attract dies having a first material thereon.

13. The system of claim 12, wherein the die receptacle structure is a web of substrates.

14. The system of claim 12, wherein the die receptacle structure is a substrate.

15. The system of claim 12, wherein the die receptacle structure is a die holder.

16. The system of claim 12, wherein each cell has a rectangular shaped cross-section.

17. The system of claim 12, wherein each cell has a trapezoidal shaped cross-section.

18. The system of claim 12, wherein the die receptacle structure has a layer that forms the bottom surface of each cell.

19. The system of claim 18, wherein the first material is a magnetic material, wherein the layer comprises a metal to be magnetically attracted to the first material of the dies.

20. The system of claim 18, wherein the layer comprises a magnetic material to magnetically attract the first material of the dies.

21. The method of claim 19, further comprising:
a voltage source coupled to said layer to apply a bias voltage to the layer to electrostatically attract the first material of the dies.

22. The method of claim 12, wherein the bottom surface of each cell is treated with a first material to chemically attract the first material of the dies.
